(19) United States
(12) Patent Application Publication
(10) Pub. No.: US 2025/0157882 A1
(43) Pub. Date: May 15, 2025

(54) SYSTEMS AND METHODS FOR COOLING AN INTEGRATED CIRCUIT

(71) Applicant: Advanced Micro Devices, Inc., Santa Clara, CA (US)

(72) Inventors: ZhiXin Yao, Shanghai (CN); Lan Li, Shanghai (CN); JianMing Jin, Shanghai (CN)

(73) Assignee: Advanced Micro Devices, Inc., Santa Clara, CA (US)

(21) Appl. No.: 18/506,479

(22) Filed: Nov. 10, 2023

(51) Int. Cl. H01L 23/467; H01L 23/433

(52) U.S. Cl. CPC H01L 23/467; H01L 23/433

(57) ABSTRACT

A disclosed method for cooling an integrated circuit can include positioning a first blower to draw air through a first air inlet in a first side of a housing. The method can additionally include positioning a second blower to draw air through a second air inlet in a second side of the housing that is opposite the first side, wherein the second blower is mirror-stacked with the first blower. Various other methods and systems are also disclosed.

### BACKGROUND

An integrated circuit or monolithic integrated circuit (e.g., an IC, a chip, or a microchip) is a set of electronic circuits on one small flat piece (e.g., chip) of semiconductor material, usually silicon. Integrated circuits can be implemented in various forms, such as expansion cards (e.g., graphics accelerator cards).

In computing, an expansion card (e.g., an expansion board, adapter card, peripheral card, or accessory card) is a printed circuit board that can be inserted into an electrical connector, or expansion slot (e.g., bus slot) on a computer's motherboard (e.g., backplane) to add functionality to a computer system. Sometimes the design of the computer's case and motherboard involves placing most or all of these slots onto a separate, removable card. Typically, such cards are referred to as riser cards in part because they project upward from the board and allow expansion cards to be placed above and parallel to the motherboard. Various standards define requirements for expansion cards, including power delivery requirements and form factors. One such standard corresponds to open compute project (OCP) accelerator module (OAM) for graphics accelerator cards.

A graphics card (e.g., video card, display card, graphics adapter, VGA card/VGA, video adapter, display adapter, or graphics processing unit (GPU)) is a computer expansion card that can generate a feed of graphics output to a display device such as a monitor. Graphics cards are sometimes called discrete or dedicated graphics cards to emphasize their distinction from an integrated graphics processor on the motherboard or the central processing unit (CPU). A GPU that performs the necessary computations is the main component in a graphics card.

Most graphics cards are not limited to simple display output. The GPU can be used for additional processing, which reduces the load from the CPU. Additionally, some computing platforms allow using graphics cards for general-purpose computing. Applications of general-purpose computing on graphics cards include artificial intelligence (AI) training, cryptocurrency mining, and molecular simulation. An AI accelerator is a class of specialized hardware accelerator or computer system designed to accelerate artificial intelligence and machine learning applications, including artificial neural networks and machine vision.

Usually, a graphics card comes in the form of a printed circuit board (e.g., expansion board) that can be inserted into an expansion slot. Others can have dedicated enclosures, and they can be connected to the computer via a docking station or a cable. These are known as external GPUs (eGPUs). Graphics cards are often preferred over integrated graphics for increased performance.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for cooling an integrated circuit.

FIG. 2 is a rising view of an example integrated circuit enclosure.

FIG. 3 is an exploded view of the integrated circuit enclosure of FIG. 2.

FIG. 4 is a detailed view of the integrated circuit enclosure of FIG. 3.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for cooling an integrated circuit (e.g., graphics card). For example, the disclosed systems and methods introduce a mirror stacked dual-inlet, dual-blower solution for processor cooling integrated with a heat sink (e.g., a three-dimensional (3D) vapor chamber (VC)) to increase volumetric flow rate and enhance overall thermal solution cooling capacity. With this implementation, dual fully open inlets can draw more cold air into a graphics card from both sides. Moreover, the cold air can be pushed through a 3D VC fin stack directly to take the heat generated by the high-power GPU card out of the card/chassis through a large opening of an input-output bracket. With this structure, the graphics card can run at high graphics power to support higher competing demands and higher data transmission speed within peripheral component interconnect express (PCIE) compliance for most chassis in the market.

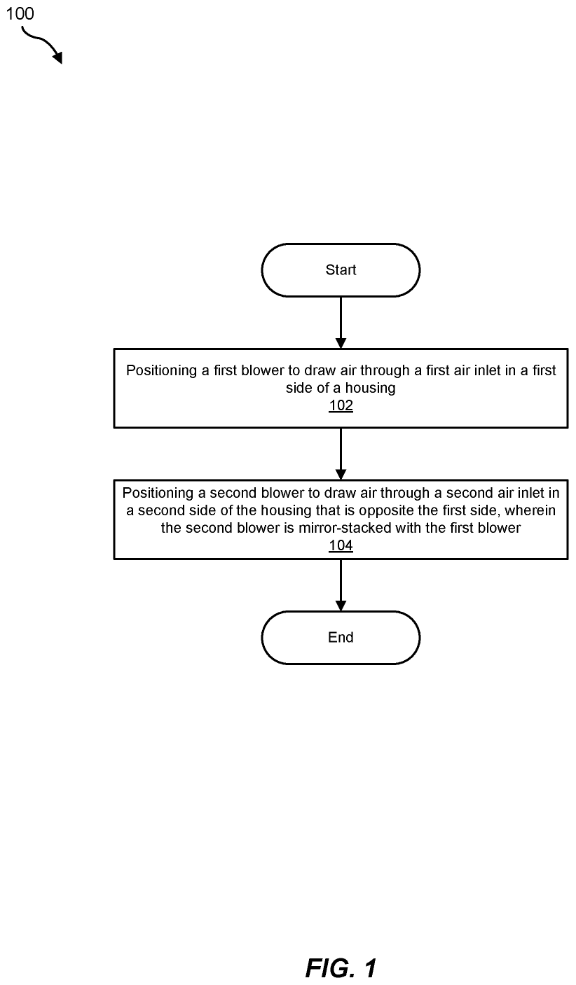

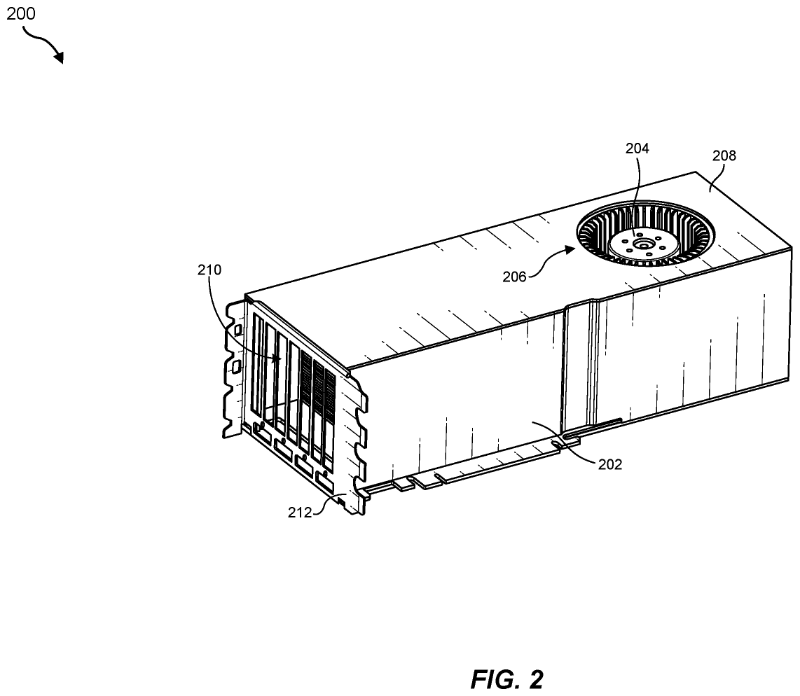

The following will provide, with reference to FIG. 1, detailed descriptions of example methods for cooling integrated circuits. In addition, detailed descriptions of example integrated circuit enclosures will be provided in connection with FIGS. 2-4.

In one example, an integrated circuit enclosure can include a housing, a first blower positioned to draw air through a first air inlet in a first side of the housing, and a second blower mirror-stacked with the first blower and positioned to draw air through a second air inlet in a second side of the housing that is opposite the first side.

Another example can be the previously described example integrated circuit enclosure, further including an air guide positioned within the housing and having the first blower and the second blower located therein.

Another example can be any of the previously described example integrated circuit enclosures, further including a heat sink positioned within the housing at a location that receives air from the air guide.

Another example can be any of the previously described example integrated circuit enclosures, further including an air outlet in a third side of the housing that is orthogonal to the first side and the second side, wherein the heat sink is located between the air guide and the air outlet.

Another example can be any of the previously described example integrated circuit enclosures, further including a mounting bracket integral to the housing and configured to hold the heat sink in a position to cool an integrated circuit mounted in the housing.

Another example can be any of the previously described example integrated circuit enclosures, further including a middle frame integral to an interior of the air guide in a position between the first blower and the second blower.

Another example can be any of the previously described example integrated circuit enclosures, wherein the middle frame has one or more cut outs formed therein that are dimensioned to balance, at least partially, air pressure between upper and lower portions of the air guide.

In one example, a cooling system can include a housing including an air guide having mirror-stacked dual blowers positioned therein, a top plate including a first air inlet positioned above the air guide, and a bottom plate including a second air inlet positioned below the air guide, an integrated circuit mounted in the housing, and a heat sink mounted in the housing and positioned to cool the integrated circuit.

Another example can be the previously described example cooling system, further including an input-output bracket including an air outlet.

Another example can be the previously described example cooling system, wherein the heat sink is located between the air guide and the input-output bracket.

Another example can be any of the previously described example cooling systems, wherein the air guide is configured to push air drawn from the first air inlet and the second air inlet by the mirror-stacked dual blowers through a fin stack of the heat sink to the air outlet.

Another example can be any of the previously described example cooling systems, further including a middle frame integral to an interior of the air guide in a position between the mirror-stacked dual blowers.

Another example can be any of the previously described example cooling systems, wherein the middle frame has one or more cut outs formed therein that are dimensioned to balance, at least partially, air pressure between upper and lower portions of the air guide.

In one example, a method can include positioning a first blower to draw air through a first air inlet in a first side of a housing and positioning a second blower to draw air through a second air inlet in a second side of the housing that is opposite the first side, wherein the second blower is mirror-stacked with the first blower.

Another example can be the previously described example method, further including positioning an air guide within the housing, wherein the air guide has the first blower and the second blower located therein.

Another example can be any of the previously described example methods, further including positioning a heat sink within the housing at a location that receives air from the air guide through a fin stack of the heat sink.

Another example can be any of the previously described example methods, further including forming an air outlet in a third side of the housing that is orthogonal to the first side and the second side, wherein the heat sink is located between the air guide and the air outlet.

Another example can be any of the previously described example methods, further including forming a mounting bracket integral to the housing and configured to hold the heat sink in a position to cool an integrated circuit mounted in the housing.

Another example can be any of the previously described example methods, further including positioning a middle frame integral to an interior of the air guide between the first blower and the second blower.

Another example can be any of the previously described example methods, wherein the middle frame has one or more cut outs formed therein that are dimensioned to balance, at least partially, air pressure between upper and lower portions of the air guide.

FIG. 1 is a flow diagram of an example method 100 for cooling an integrated circuit. As illustrated in FIG. 1, step 102 can include positioning a blower. For example, step 102 can include positioning a first blower to draw air through a first air inlet in a first side of a housing.

The term “blower,” as used herein, can generally refer to a device that creates a current of air. For example, and without limitation, a blower can include a circular array of straight or angled blades that, when rotated, motivate air to flow from one location (an outside of a housing) to another (e.g., an inside of a housing) by creating a pressure differential.

The term “air inlet,” as used herein, can generally refer to an opening, structure, or system through which air is admitted to a space or machine as a consequence of a pressure differential between an outside and an inside. For example, and without limitation, an air inlet can correspond to an opening in a housing of an integrated circuit enclosure.

The term “housing,” as used herein, can generally refer to a rigid casing. For example, a housing can correspond to a rigid casing that encloses and protects a piece of moving or delicate equipment (e.g., an integrated circuit). In some examples, an air guide can be included within the housing. In some of these examples, a middle frame can be positioned in an interior of the air guide and at least partially divide the air guide into upper and lower portions. In some examples, the middle frame can be integral (e.g., formed as one piece, permanently attached, removably fastened, etc.) to the air guide. In some examples, the middle frame can have one or more cut outs formed therein. In some of these examples, the cutouts can be located proximate to a perimeter of the middle frame. In some examples, the housing can be shaped as a cuboid and the air guide can be located at one end of the cuboid with air inlets located on sides of the housing that are opposite one another. In some examples, the air guide can be shaped as a involute curve that is open on the ends thereof to interface with air inlets and can have another opening on a side thereof for guiding of air through an interior of the housing toward another end of the cuboid.

Step 102 can be performed in a variety of ways. In one example, step 102 can include positioning the first blower within the air guide. In some of these examples, step 102 can include placing the first blower in one of the upper and lower portions of the air guide with an orientation that draws air into the air guide through the first air inlet located at an end of the air guide (e.g., on one side of the housing). In some implementations, the first blower can have dimensions that avoid covering cutouts in a middle frame within the air guide.

Step 104 can include positioning another blower. For example, step 104 can include positioning a second blower to draw air through a second air inlet in a second side of the housing that is opposite the first side, wherein the second blower is mirror-stacked with the first blower.

The term “mirror stacked,” as used herein, can generally refer to a relationship of position and operation. For example, and without limitation, blowers can be mirror stacked when one blower is stacked atop the other and the blowers are configured to rotate in a same direction while drawing air from opposite directions. In some of these examples, the blowers can rotate at a same rate during operation. If blades of the blowers are configured and aligned to affect mirror images of one another, and if the blades are aligned, then one blower can appear to be a mirror image of the other before, during, and after operation. However, variations in appearance that do not significantly impact the functionality of the stacked blowers do not prevent the blowers from being mirror stacked.

Step 104 can be performed in a variety of ways. In one example, step 104 can include positioning the second blower within the air guide so that the first blower is mirror stacked with the second blower. For example, step 104 can include placing the second blower in the other portion of the upper and lower portions of the air guide with an orientation that draws air into the air guide through the second air inlet located at the other end of the air guide (e.g., on the opposite side of the housing). Mirror stacking the second blower and the first blower can allow the blowers to draw air through the first inlet and the second inlet when they rotate in a same direction and, in some implementations, at a same rate. In some of these implementations, both the first blower and the second blower can be attached to a same element (e.g., a middle frame). In some implementations, the second blower can have dimensions that avoid covering cutouts in a middle frame within the air guide. These cut outs can be dimensioned to balance, at least partially, air pressure between upper and lower portions of the air guide.

Steps 102-104 can include various additional sub-steps. In some examples, steps 102-104 can include positioning a heat sink within the housing at a location that receives air from the air guide through a fin stack of a (e.g., three-dimensional vapor chamber based) heat sink. In some of these examples, steps 102-104 can include forming an air outlet in a third side of the housing that is orthogonal to the first side and the second side, wherein the heat sink is located between the air guide and the air outlet. Alternatively or additionally, steps 102-104 can include forming a mounting bracket integral to the housing and configured to hold the heat sink in a position to cool an integrated circuit mounted in the housing. Additional details relating to these and other features of method 100 are provided below with reference to FIGS. 2-4.

FIG. 2 illustrates an example integrated circuit enclosure 200. For example, integrated circuit enclosure 200 can include a housing 202 shaped as a cuboid. A blower 204 within housing 202 can draw air into housing 202 through an air inlet 206 formed in a top plate 208 of housing 202. Air drawn into housing 202 in this manner can travel through an interior of housing 202 and exit through an air outlet 210 formed in an input-output (IO) bracket 212 at an end of integrated circuit enclosure 200 on a side of housing 202 that is orthogonal to top plate 208.

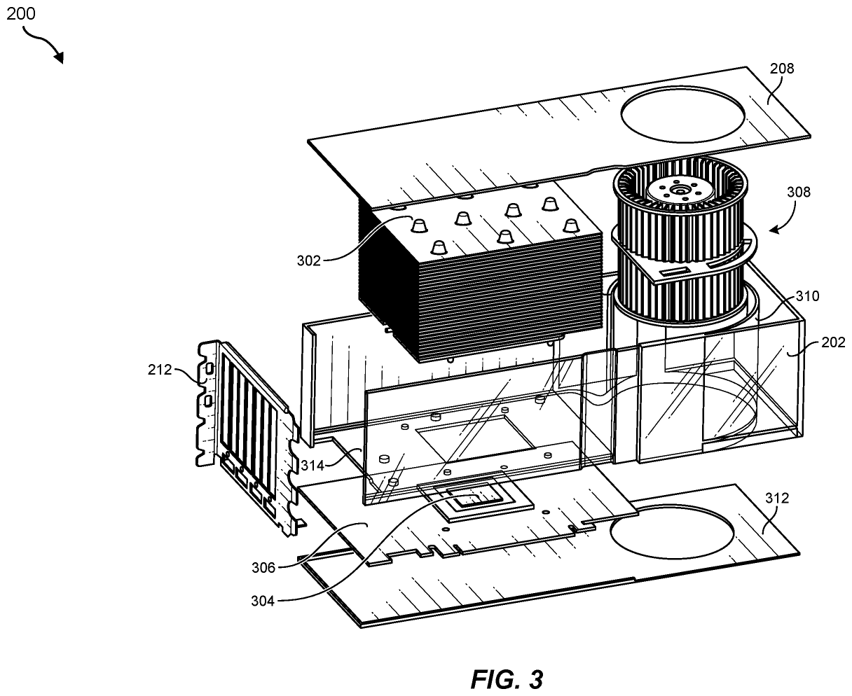

FIG. 3 illustrates additional features of the integrated circuit enclosure 200 of FIG. 2. For example, in addition to housing 202, top plate 208, 10 bracket 212, and other features shown in FIG. 2, integrated circuit enclosure 200 can include a heat sink 302 having a 3D VC, an integrated circuit 304 (e.g., application specific integrated circuit (ASIC), graphics card, etc.), a printed circuit board assembly (PCBA) 306, an integrated mid-frame dual blower array 308 within an air guide 310, a bottom plate 312 having another air inlet on a side of housing 202 opposite top plate 208, and a mounting bracket 314 integral to housing 202. In some implementations, PCBA 306 can attach to an underside of mounting bracket 314, which can have an opening through which integrated circuit 304 can protrude to a top side of mounting bracket 314. In some of these implementations, heat sink 302 can attach to a top side of mounting bracket 314 and rest in contact with integrated circuit 304. Integrated mid-frame dual blower array 308 can draw air through top and bottom air inlets in housing 202 into air guide 310, which can direct the air through a fin stack of a (e.g., three-dimensional vapor chamber based) heat sink 302 to a large air outlet in IO bracket 212.

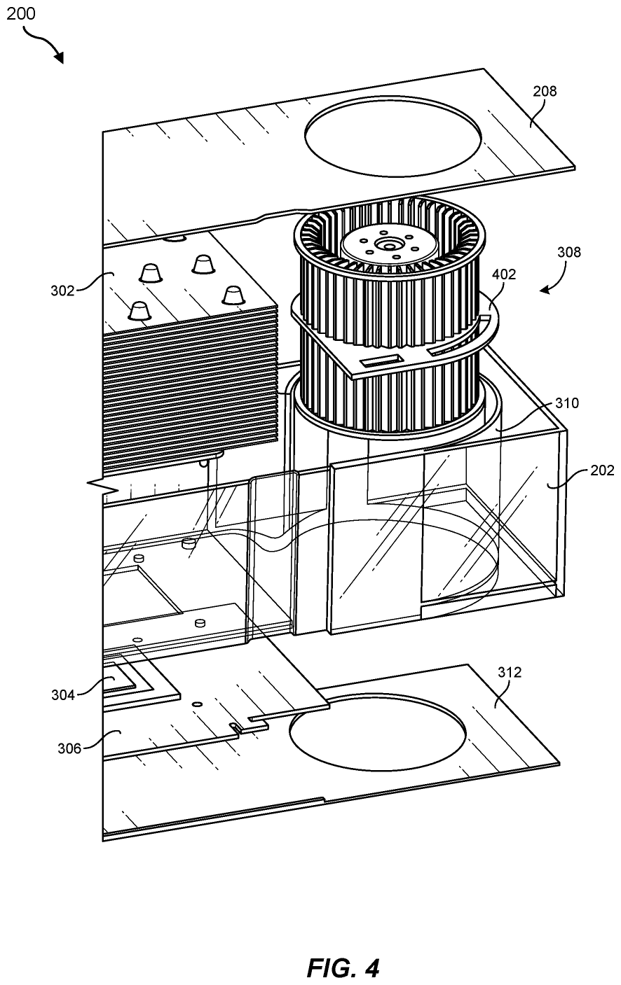

FIG. 4 illustrates some of the additional features of the integrated circuit enclosure 200 of FIGS. 2 and 3 in greater detail. For example, integrated circuit enclosure 200 can include housing 202, top plate 208, IO bracket 212, heat sink 302, integrated circuit 304, PCBA 306, integrated mid-frame dual blower array 308 within air guide 310, and bottom plate 312. In addition, integrated circuit enclosure 200 can have a middle frame 402 within air guide 310. Middle frame 402 can be positioned in an interior of air guide 310 and at least partially divide air guide 310 into upper and lower portions. In some examples, middle frame 402 can be integral (e.g., formed as one piece, permanently attached, removably fastened, etc.) to air guide 310. In some examples, middle frame 402 can have one or more cut outs formed therein. In some of these examples, the cutouts can be located proximate to a perimeter of middle frame 402. The cut outs can be dimensioned to equalize air pressure, at least partially, between the upper and lower portions of air guide 310. Thus, if one of the air inlets is partially covered, blower array 308 can still deliver air drawn from both air inlets through the fin stack of heat sink 302.

As set forth above, the systems and methods disclosed herein can yield numerous benefits. For example, required space for graphics cards is trending to three or even four slots from a previous one or two slots. To fully utilize the increased volume of the thermal solution, a more efficient cooling architecture can boost GPU performance. However, current blower cooled GPU cards typically have one centrifugal fan on one end of the GPU card enclosure. With such an arrangement, a maximum cooling capacity can be limited to about 220 Watts in dual slot GPU designs.

To further improve the cooling performance with one ultra-thick (e.g., three or four slot) blower and heatsink, there can be two main disadvantages. For example, the ultra-thick blower can have higher flow resistance to draw in the fresh air efficiently, especially with the blade parts close to the blower base. Also, a traditional two-dimensional VC or one-dimensional heat pipe thermal solution cannot make full use of the space to spread the heat uniformly.

The disclosed mirror stacked dual-inlet, dual-blower system for processor cooling integrated with 3D VC can increase the volumetric flow rate and enhance the overall thermal solution cooling capacity. With this implementation, dual fully open inlets can be achieved to draw more cold air into the card from both sides. Moreover, the cold air can be pushed through a 3D VC fin stack directly to take the heat generated by the high-power GPU card out of the card/chassis through the large opening of the IO Bracket. With this architecture, the graphics card can run at high graphic power to support higher competing demands and higher data transmission speed within PCIE compliance for most chassis in the market.

Example features of the disclosed mirror stacked, dual-inlet, dual-blower system can include an integrated mid-frame dual blower array implementation. Additional features can include reserve space for the air mover and smart application of an integrated middle-frame designed to support dual-blowers. The disclosed system can also introduce fully open inlets on both sides for double air flow and enhancement of heatsink performance under a same acoustic level. Further, pressure balance cutouts can reduce potential back flow loss. Still further features can include a 3D VC with an optimized fin stack to take the heat from the ASIC and PCBA to the whole volume of the heatsink efficiently.

Combinations of the above features can yield numerous benefits. For example, with the mirror stacked, dual-inlet, dual-blower solution, the flow rate of cold air through the graphics card can be increased to support higher power. Additionally, the fan diameter and thickness can be optimized to a golden ratio to improve air mover performance. Also, cold air can be driven towards the 3D VC directly so that heat can be dissipated out of the card/chassis through the large opening of the IO Bracket. Finally, acoustic improvement can be achieved with dual inlets located on opposite sides of the graphics card enclosure so that sound waves can be separated, thus reducing sound pressure levels to end users.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An integrated circuit enclosure, comprising:
a housing;
a first blower positioned to draw air through a first air inlet in a first side of the housing; and
a second blower mirror-stacked with the first blower and positioned to draw air through a second air inlet in a second side of the housing that is opposite the first side.

2. The integrated circuit enclosure of claim 1, further comprising:
an air guide positioned within the housing and having the first blower and the second blower located therein.

3. The integrated circuit enclosure of claim 2, further comprising:
a heat sink positioned within the housing at a location that receives air from the air guide.

4. The integrated circuit enclosure of claim 3, further comprising:
an air outlet in a third side of the housing that is orthogonal to the first side and the second side, wherein the heat sink is located between the air guide and the air outlet.

5. The integrated circuit enclosure of claim 3, further comprising a mounting bracket integral to the housing and configured to hold the heat sink in a position to cool an integrated circuit mounted in the housing.

6. The integrated circuit enclosure of claim 2, further comprising a middle frame integral to an interior of the air guide in a position between the first blower and the second blower.

7. The integrated circuit enclosure of claim 6, wherein the middle frame has one or more cut outs formed therein that are dimensioned to balance, at least partially, air pressure between upper and lower portions of the air guide.

8. A cooling system, comprising:
a housing including an air guide having mirror-stacked dual blowers positioned therein, a top plate including a first air inlet positioned above the air guide, and a bottom plate including a second air inlet positioned below the air guide;
an integrated circuit mounted in the housing; and
a heat sink mounted in the housing and positioned to cool the integrated circuit.

9. The cooling system of claim 8, further comprising an input-output bracket including an air outlet.

10. The cooling system of claim 9, wherein the heat sink is located between the air guide and the input-output bracket.

11. The cooling system of claim 10, wherein the air guide is configured to push air drawn from the first air inlet and the second air inlet by the mirror-stacked dual blowers through a fin stack of the heat sink to the air outlet.

12. The cooling system of claim 8, further comprising a middle frame integral to an interior of the air guide in a position between the mirror-stacked dual blowers.

13. The cooling system of claim 12, wherein the middle frame has one or more cut outs formed therein that are dimensioned to balance, at least partially, air pressure between upper and lower portions of the air guide.

14. A method comprising:
positioning a first blower to draw air through a first air inlet in a first side of a housing; and
positioning a second blower to draw air through a second air inlet in a second side of the housing that is opposite the first side, wherein the second blower is mirror-stacked with the first blower.

15. The method of claim 14, further comprising:
positioning an air guide within the housing, wherein the air guide has the first blower and the second blower located therein.

16. The method of claim 15, further comprising:
positioning a heat sink within the housing at a location that receives air from the air guide through a fin stack of the heat sink.

17. The method of claim 16, further comprising:
forming an air outlet in a third side of the housing that is orthogonal to the first side and the second side, wherein the heat sink is located between the air guide and the air outlet.

18. The method of claim 16, further comprising:
forming a mounting bracket integral to the housing and configured to hold the heat sink in a position to cool an integrated circuit mounted in the housing.

19. The method of claim 15, further comprising:
positioning a middle frame integral to an interior of the air guide between the first blower and the second blower.

20. The method of claim 19, wherein the middle frame has one or more cut outs formed therein that are dimensioned to balance, at least partially, air pressure between upper and lower portions of the air guide.
